(19) United States
(12) Patent Application Publication
(10) Pub. No.: US 2012/0212115 A1
(43) Pub. Date: Aug. 23, 2012

(54) WINDOW GLASS MOUNTED FASTENER

(75) Inventor: Brian Bentrim, Furlong, PA (US)

(73) Assignee: PEM MANAGEMENT, INC., Wilmington, DE (US)

(21) Appl. No.: 13/398,928

(22) Filed: Feb. 17, 2012

Related U.S. Application Data
(60) Provisional application No. 61/444,260, filed on Feb. 18, 2011.

(51) Int. Cl. H05K 5/02; H05K 5/00

(52) U.S. Cl. 312/223.4; 312/223.1

(57) ABSTRACT

A soldered fastening device mounts a glass plate to a support structure, for example, a window glass mounted to the housing of an electronic device such as a cell phone. The fastening device affixed to a rear surface of the window by solder threadably engages a housing fastener to rigidly secure the window to the housing. The soldering process is preferably wave soldering and the fastening device can have an internally threaded axial bore which is either perpendicular to or parallel to the surface of the window for receiving the fastener, such as a screw.

### FIELD OF THE INVENTION

The present invention relates to the use of a fastener soldered to glass for the attachment of other devices to the glass plate. More specifically, it relates to a fastener surface mount soldered to a glass plate used as means for attaching a window glass to a chassis of an electronic device such as a cell phone.

### BACKGROUND OF THE INVENTION

Soldering to glass, while not widely done, is known in the art. A common application is the soldering of an antenna attachment on the back window of a car. However, the glass itself is typically held to the car by a glued in place gasket on the metal frame.

Many cell phones are more frequently using a full glass front panel. This currently leaves the manufacturer no option but to glue or creatively gasket and fixture the glass. These options often leave the product designer less than optimal aesthetic solutions. Because of its brittle nature, structurally mounting a glass plate is a difficult process. Adhesives feature prominently in the arsenal of fastening methods available, however adhesives have some serious drawbacks. Generally adhesives are not recyclable, in fact they are often poisons to recycling meaning their presence can prevent a batch of material from being recycled. Adhesives also offer some challenges to manufacturing and are frequently not preferred in a manufacturing environment. Tempered glass cannot easily be drilled or modified to place bolt holes. Usually clips and hooks are employed to fasten and fixture the glass, but these are often imprecise and inexact methods that allow for some movement in the final position.

### SUMMARY OF THE INVENTION

In order to meet the needs in the art described above, the present invention enables firm fixturing of glass to a frame or chassis through the use of a soldered-on mechanical fastening device. The soldering can be done in numerous ways, but the most economical is to first put a localized solderable coating on the glass and then use surface mount technology to solder a fastener to the glass. The present fastener combination assembly is non-intrusive and does not cut into the glass so the tempering and structure of the glass remains unchanged. The soldering temperatures are low enough to not interfere with the atomic structure of most glasses as well.

The fastening device soldered to the glass can be of a variety of configurations. Most typical would be a threaded nut or stud that is then engaged to the chassis. That threaded fastening device could be affixed so that the threads are aligned normally to the surface of the glass or parallel to the glass surface. While threaded fasteners are the most universally acceptable, buttons, pins and snaps can also be used as well as other common simple fastening devices. To solder any of these fasteners to the glass, a coating must first be applied to the glass to provide a solderable finish. This coating may be tin, silver, copper, gold or another solderable metal. Applying this finish to the glass is not uncommon and can be done by many coaters in the glass industry.

The soldering of a fastening device to the glass and mounting the glass structure with that element is a unique aspect of the invention. This becomes very useful in industries that want to use glass, while minimizing the surrounding elements, for example cell phone display windows. More specifically, the applicant has invented a combination of a window glass and a housing of an electronic device wherein the housing has a member having an aperture for receiving an externally threaded fastener. That fastener secures a transparent glass window by an internally threaded female fastening device having a base affixed with a rear surface of the window by soldering while threadably engaging the fastener to rigidly secure the window to the housing. The soldering process is preferably by wave soldering and the fastening device can have an internally threaded axial bore which is either perpendicular to or parallel to the surface of the window. Typically, the fastener will be the screw and the housing member can be planar and parallel to the window in some cases.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods, and systems for carrying out the several purposes of the present invention.

### BRIEF DESCRIPTION OF THE DRAWINGS

FIG. 1 is a top right front isometric view showing the invention as an assembly using a right-angle soldered fastener.

FIGS. 2 and 3 are top right rear isometric views of the embodiment shown in FIG. 1.

FIG. 4 is a three-part top right rear exploded assembly view.

FIG. 5 is a top right rear isometric view using a spacer-nut soldered fastener.

FIG. 6 is a top right front isometric view of the embodiment shown in FIG. 5.

FIG. 7 is a top right rear isometric exploded view of the assembly of FIG. 6.

### DESCRIPTION OF THE PREFERRED EMBODIMENT

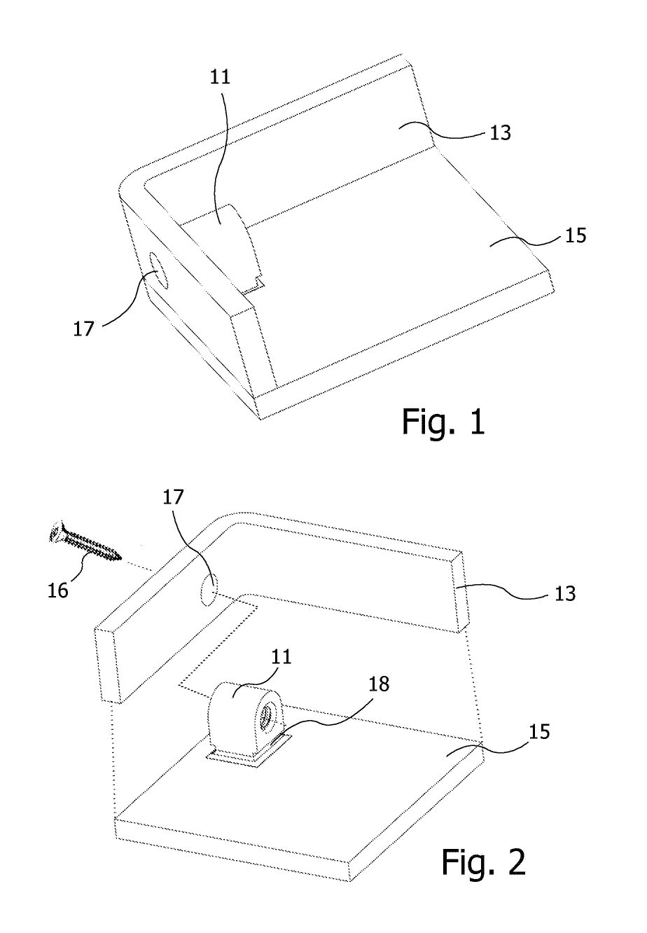

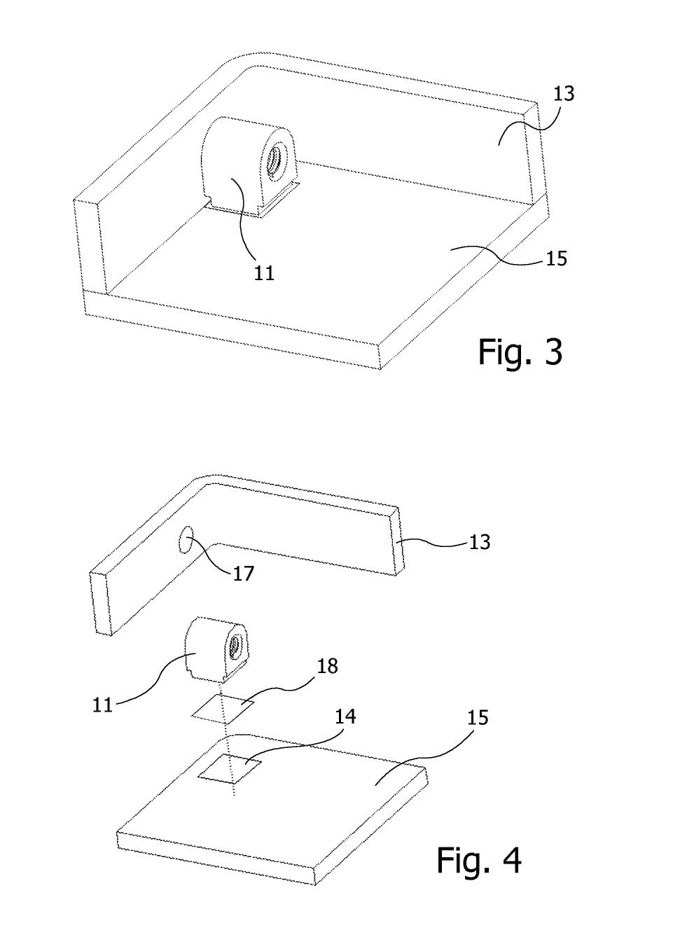

FIGS. 1-4 show different views of one embodiment of the invention in which right-angled fastening device 11 attaches a chassis member 13 to a glass plate 15. The chassis member shown in this embodiment is depicted as an L-shaped framework chosen for illustration only. It should be understood that the chassis member may be of any suitable configuration to be compatible with the fastening device 11. An aperture 17 in the chassis member is in alignment with the fastening device 11 to receive a mating fastener such as a screw. FIG. 2 shows the chassis member removed from the fastening device and plate that may be reattached by screw 16 passing through aperture 17 into fastening device 11. A layer of solder 18 affixes the fastening device to the glass plate. FIGS. 3 and 4 are rear views showing the embodiment of FIG. 1 and the assembly of its parts as shown in FIG. 4. As shown in FIG. 4, glass plate 15 is first coated with a solder receiving layer 14 in a region where fastening device 11 is placed. The fastener is then secured to the plate by a layer of solder 18 placed between the fastening device and the coating 14 such as by surface mount soldering well known in the electronic arts.

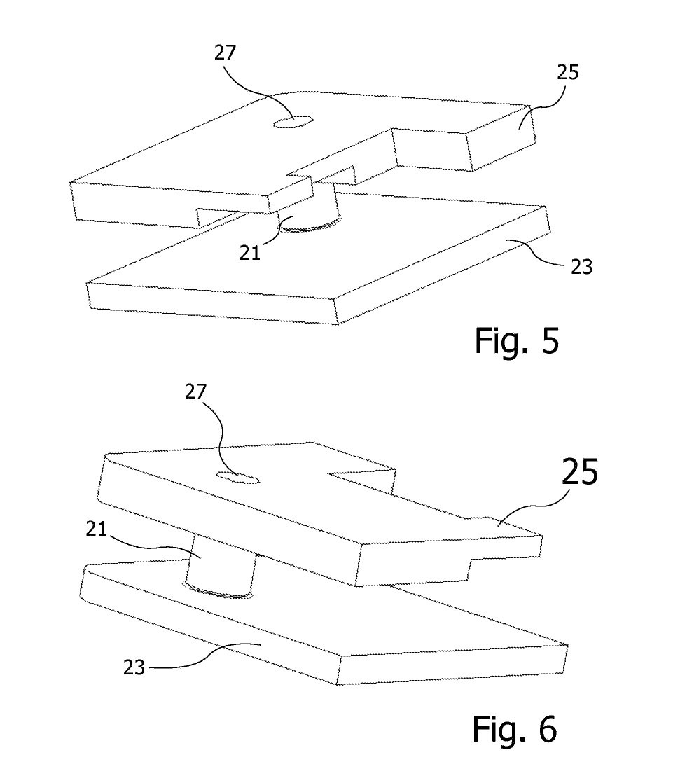

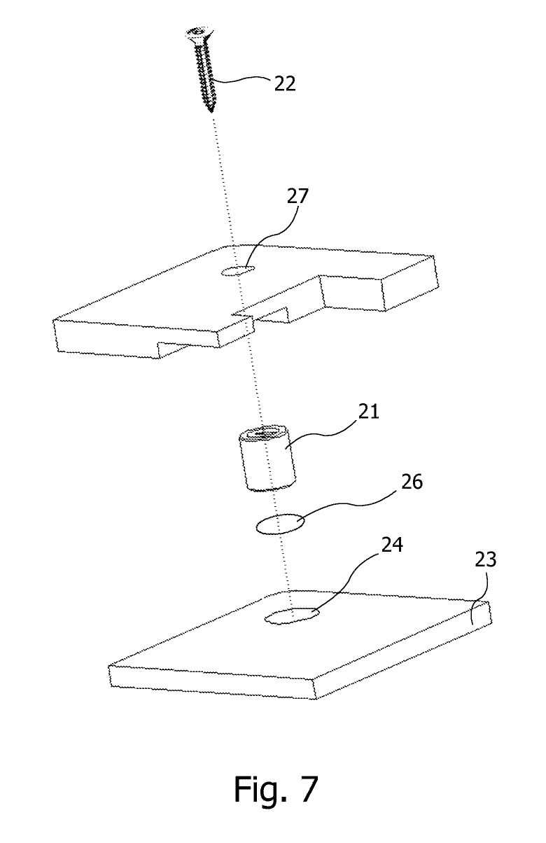

FIGS. 5-7 show another embodiment in which a standoff-type fastening device 21 is soldered to a glass plate 23 to interconnect chassis member 25 by screw means shown in FIG. 7 that passes through aperture 27 which is in alignment with an axial bore of fastening device 21. This embodiment demonstrates the attachment of a chassis member 25 parallel to glass plate 23 which by example may be the window glass of a handheld electronic device such as a cell phone. The assembly view of this embodiment shown in FIG. 7 describes the same assembly process as the previous embodiment shown in FIGS. 1-4. A solder receiving coating is first laid down on the glass plate 23 in region 24. Fastening device 21 is then soldered to plate 23 in this region by deposition of solder 26. Chassis member 25 is then placed over the fastener with aperture 27 in alignment with a screw receiving threaded bore of fastening device 21. The screw is then inserted through the chassis aperture into the fastener bore and tightened.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

What is claimed as being new and desired to be protected by Letters Patent of the United States is as follows:

What is claimed is:

1. In combination, a window glass and a housing of an electronic device, comprising:
a housing member having an aperture for receiving a fastener;
a transparent glass window; and
a fastening device having a base affixed to a rear surface of said window by soldering while engaging said fastener to rigidly secure the window to the housing.

2. The combination of claim 1 wherein said soldering is wave soldering.

3. The combination of claim 1 wherein said fastening device has an internally threaded axial bore which is perpendicular to the surface of said window.

4. The combination of claim 1 wherein said fastening device includes an internally threaded bore which is parallel to the surface of said window.

5. The combination of claim 1 wherein said fastener is a screw.

6. The combination of claim 1 wherein the housing is a chassis of an electronic device.

7. The combination of claim 6 wherein the electronic device is a cell phone.

8. The combination of claim 3 wherein the housing member is planar and parallel to said window.
